(19) United States
(12) Patent Application Publication
(10) Pub. No.: US 2016/0079731 A1
(43) Pub. Date: Mar. 17, 2016

(54) Blue Laser Aiming Device

(71) Applicants: Carson Cheng, City of Industry, CA (US); Changan Tian, City of Industry, CA (US)

(72) Inventors: Carson Cheng, City of Industry, CA (US); Changan Tian, City of Industry, CA (US)

(73) Assignee: NCSTAR, INC., City of Industry, CA (US)

(21) Appl. No.: 14/485,775

(22) Filed: Sep. 14, 2014

(51) Int. Cl. H01S 5/0625; F41G 1/35; H01S 3/10; H01S 5/068; H01S 3/00; H01S 5/062

(52) U.S. Cl. CPC H01S 5/06253; H01S 3/0007; H01S 5/06216; H01S 3/10; H01S 5/06804; F41G 1/35

(57) ABSTRACT

A laser aiming device includes a laser generator and a module activating the laser generator to generate a non-continuous laser beam in order to form a bright spot of light in a flickering manner that a flickering interval of the bright spot of light is short enough not to be noticed by a human eye. A pulse width modulation (PWM) of the control module modulates the laser beam in form of rectangular pulse wave to control an output power of the non-continuous laser beam being not exceed 5 mW continuous wave.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

The present invention relates to sight device for firearm, and more particular to a blue laser aiming device for a firearm, which generates a blue laser beam in low output power for safety purpose.

2. Description of Related Arts

Conventional firearm, such as a gun or a rifle, usually needs different firearm accessories for assisting the operator to accurately locate the target and perform the shooting. Laser sight is one of the sighting devices and is commonly used in conjunction firearms, such as rifles, to give an accurate aiming point and to aid the operator in properly aligning a barrel of the firearm with a desired target.

The laser sight generally comprises a laser generator activated to generate a continuous laser beam to form a spot of light that is visible to the human eye. In other words, the laser generator is continuously activated that generate the bright laser beam highly visible to the human eye in appropriate lighting conditions. Generally speaking, the laser beam may be a red, green, or blue laser. However, different laser generators will generate different laser beams in different output powers. Moderate and high-power lasers are potentially hazardous because they can burn the retina of the eye or even the skin.

According to the FDA regulation, the energy output of hand-held laser pointers must not be exceed 5 milliwatts (mW) continuous wave. Red laser and green laser are commonly used because the red laser generator and green laser require relatively low input power to activate. As a result, the output powers of the red laser and green laser will not exceed 5 mW. On the other hand, blue laser generator requires relative high input power to activate, such that the output power of the blue laser will exceed 5 mW. In particular, the output power of the blue laser must be greater than 100 mW in order to form the bright spot of blue light. If reducing the output power of the blue laser to not exceed 5 mW, the brightness of the blue laser will significantly reduced and the spot of blue light will be blurred. Such low output power of blue laser will not meet the requirement as a sighting device. Accordingly, since the blue laser sighting device is not safe, some users would like to use it because it reflects the individual unique aesthetic taste.

Therefore, the user who uses the blue laser should be aware of the risks. It is required that the use of eye protection when operating the blue lasers. The protective eyewear in form of spectacles or goggles to block or attenuate in the appropriate blue wavelength range can protect the eyes from the reflected or scattered blue laser light with a hazardous output power.

### SUMMARY OF THE PRESENT INVENTION

The invention is advantageous in that it provides a laser aiming device for a firearm, which generates a laser beam in low output power for safety purpose.

Another advantage of the invention is to a laser aiming device, which generates a bright spot of light in a flickering manner that the flickering interval of the spot light is short enough not to be noticed by a human eye. In other words, the user will see the bright spot of light without any visible flicker.

Another advantage of the invention is to a laser aiming device, wherein the blue laser (blue-violet laser) is generated that an output power thereof does not exceed 5 mW continuous wave, which is safe for human eye.

Another advantage of the invention is to a laser aiming device, wherein the low powered blue laser beam generated by a laser generator has almost the same brightness of the high powered blue laser beam generated by the existing laser generator, such that the laser generator of the present invention is able to generate a low powered blue laser while being cost effective.

Another advantage of the invention is to a laser aiming device, which incorporates with a pulse width modulation (PWM) to control the output power of the laser beam.

Another advantage of the invention is to a laser aiming device, wherein a control module is operatively linked to a laser generator so as to modulate the laser beam generated by the laser generator.

Another advantage of the invention is to a laser aiming device, wherein a temperature sensor is operatively linked to the laser generator to detect an operation temperature thereof so as to optimize the output power of the laser beam.

Another advantage of the invention is to a laser aiming device, wherein a pulse duration of the pulse wave in each period thereof can be selectively adjusted by an output power controller in response to the operation temperature of the laser generator in order to stabilize the output power of the laser beam.

Additional advantages and features of the invention will become apparent from the description which follows, and may be realized by means of the instrumentalities and combinations particular point out in the appended claims.

According to the present invention, the foregoing and other objects and advantages are attained by a laser aiming device comprising a laser generator and a control module. The laser generator is activated by the control module to generate a non-continuous laser beam in order to form a bright spot of light in a flickering manner that a flickering interval of the bright spot of light is short enough not to be noticed by a human eye.

In accordance with another aspect of the invention, the present invention comprises a method of generating a low powered laser beam with an output power thereof being not exceed 5 mW continuous wave, comprising the following steps.

(A) Operatively link a laser generator to a control module.

(B) Activate the laser generator by the control module to generate a non-continuous laser beam in order to form a bright spot of light in a flickering manner that a flickering interval of the bright spot of light is short enough not to be noticed by a human eye, so as to control the output power of the non-continuous laser beam being not exceed 5 mW continuous wave.

Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a block diagram of a laser aiming device according to a preferred embodiment of the present invention.

FIG. 2 is a flow diagram of the laser aiming device according to the above preferred embodiment of the present invention, illustrating the operation of the laser aiming device.

FIG. 3 is a circuit diagram of the laser aiming device according to the above preferred embodiment of the present invention.

FIG. 4 is a graph illustrating an input current of the laser aiming device according to the above preferred embodiment of the present invention.

FIG. 5 is a graph illustrating an output power of the laser aiming device according to the above preferred embodiment of the present invention.

FIG. 6 is a perspective view of the laser aiming device according to the above preferred embodiment of the present invention.

FIG. 7 is a graph illustrating an output power in response to operation temperature according to the above preferred embodiment of the present invention.

FIG. 8 is a graph illustrating an operating voltage in response to operation temperature according to the above preferred embodiment of the present invention.

FIG. 9 is a graph illustrating a threshold current in response to operation temperature according to the above preferred embodiment of the present invention.

FIG. 10 is a graph illustrating an emission wavelength in response to operation temperature according to the above preferred embodiment of the present invention.

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

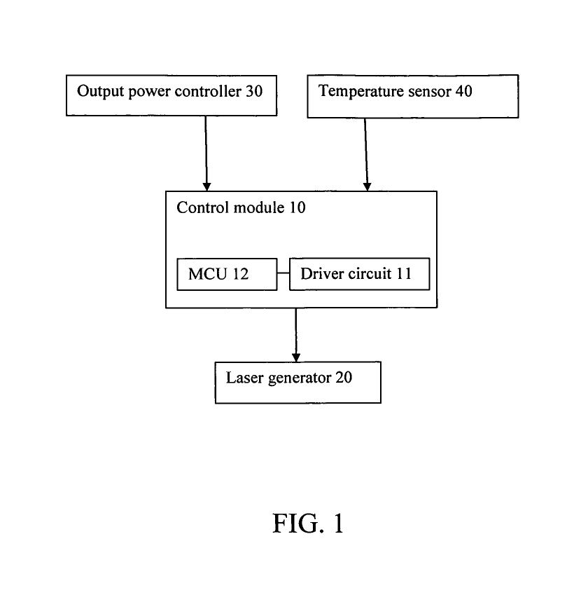

Referring to FIG. 1 of the drawings, a laser aiming device according to a preferred embodiment of the present invention is illustrated, wherein the laser aiming device comprises a control module 10 and a laser generator 20.

As shown in FIG. 1, the control module 10 which comprises a driver circuit 11 operatively linked to the laser generator 20 and a microcontroller unit (MCU) 12 operatively controlling the driver circuit 11. The driver circuit 11 of the control module 10 is arranged to activate the laser generator 20.

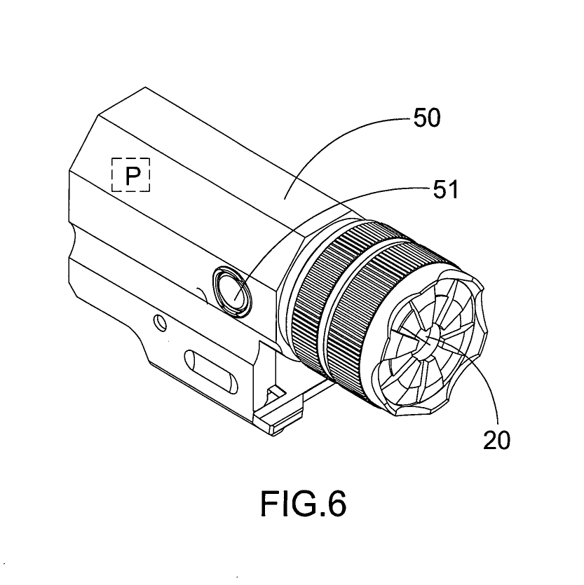

As shown in FIG. 6, the laser aiming device further comprises a casing 50 adapted for being detachably attached to a firearm via an existing attachment unit, such as “Weaver” mounting structure, “Picatinny” mounting structure, or “KeyMod” mounting structure, wherein the control module 10 and the laser generator 20 are received in the casing 50. A control switch 51 is provided at the casing 50 to switch the control module 10 in an on-and-off manner so as to initialize the control module 10 to control the laser generator 20.

When the laser generator 20 is activated by the control module 10, the laser generator 20 will generate a non-continuous laser beam in order to form a bright spot of light in a flickering manner. It is worth mentioning that the conventional laser generator will generate a continuous laser beam that an output thereof is constant. The non-continuous laser beam generated by the laser generator 20 of the present invention is that the output thereof is not constant. In addition, a flickering interval of the bright spot of light is short enough not to be noticed by a human eye. Therefore, human eye will see the bright spot of light without any visible flicker.

According to the preferred embodiment, the laser generator 20 can be a red laser generator to generate red laser beam, a green laser generator to generate green laser generator, or a blue laser generator to generator blue generator. Accordingly, the red laser generator and green laser generator require relatively low input power to activate, such that the output powers of the red laser beam and green laser generator will not be exceed a hazardous level, i.e. 5 mW continuous wave. However, blue laser generate will require relatively high input power to activate, such that the output power of the blue laser beam by the conventional blue laser generator will be exceed 5 mW continuous wave. It is worth mentioning that the output power is defined to express the rate of energy conversion with respect to time. Therefore, the continuous blue laser beam generator by the conventional blue laser generator will generate the constant output power being exceed 5 mW.

In view of the present invention, the laser generator 20 can be a blue laser generator to generate the non-continuous laser beam in blue color with the output power thereof being not exceed 5 mW continuous wave. In particular, the wavelength of the blue laser beam is about 450 nm. In order to generate the low output power of the blue laser beam, the laser generator 20 is activated in an on-and-off manner to generate the non-continuous blue laser beam. In other words, the laser generator 20 is intermittently activated to generate the non-continuous blue laser beam. As it is mentioned that the output power is defined to express the rate of energy conversion with respect to time, the output power of the non-continuous blue laser beam generated by the laser generator 20 will be controlled under 5 mW. It is worth mentioning that the low powered blue laser beam generated by the laser generator 20 of the present invention has almost the same brightness of the high powered blue laser beam generated by the conventional laser generator. In particular, the bright spot of light has a diameter of 20 mm at 20 meter away from the laser generator 20.

According to the preferred embodiment, the driver circuit 11 of the control module 10 is arranged to control the current input to the laser generator 20 and to regulate the voltage input to the laser generator 20. Accordingly, a replaceable battery P is received in the casing 50 as a power supply to electrically link to the control module 10 and the laser generator 20. The replaceable battery generally provides a 3V output voltage. However, the operating voltage of the laser generator 20, especially for blue laser generator, is about 6.3V-7V in order to stably operate the laser generator 20. In other words, more replaceable batteries must be received in the casing 50 in order to provide a stable operating voltage for the laser generator 20. However, the overall weight and size of the laser aiming device with the replaceable batteries will relatively heavy and bulk. Therefore, the driver circuit 11 of the control module 10 will regulate the output voltage of the replaceable battery from 3V to 7V as an input voltage to the laser generator 20, such that the 3V replaceable battery can be used to stably operate the laser generator 20 at 7V operating voltage via the driver circuit 11. In other words, the driver circuit 11 increases the input voltage to the laser generator 20 in order to enable the laser generator 20 to generate the laser beam in a stable manner.

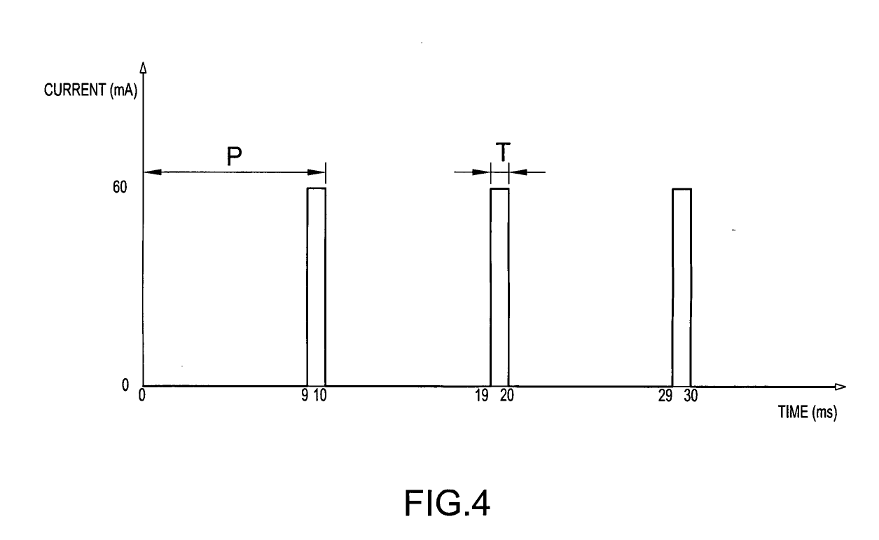

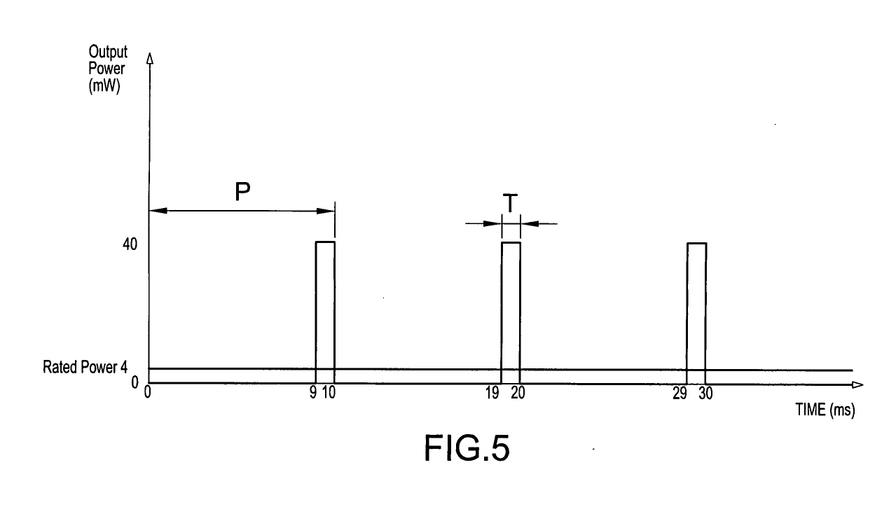

In particular, the control module 10 comprises a pulse width modulation (PWM) 13 operatively linked to the driver circuit 11 and the microcontroller unit 12, wherein the pulse width modulation 13 activates the laser generator 20 in an on-and-off manner and modulates the laser beam in form of rectangular pulse wave via the driver circuit 11, as shown in FIGS. 4 and 5, so as to enable the laser generator 20 to generate the non-continuous laser beam. Accordingly, the microcontroller unit 12 controls the pulse width modulation (PWM) 13 to regulate the input current in form of rectangular pulse wave to the driver circuit 11 so as to regulate the output power in form of rectangular pulse wave of the laser generator 20.

It is worth mentioning that the pulse width modulation 13 is a modulation technique that controls the width of the pulse, formally the pulse duration, based on the modulator signal information. The mainly use of pulse width modulation is to allow the control of the power supplied to the electrical devices. In this present invention, the microcontroller 12 generates a pulse signal and controls the width of the pulse. The signal will be sent to the driver circuit 11. The driver circuit 11 regulates the voltage from the battery P based on the pulse signal from the microcontroller 12. Therefore, an on-and-off voltage is set on the laser generator 20 to generate the non-continuous laser beam.

For the rectangular pulse wave, the output power of the laser generator 20 will define a pulse duration T and a period P, wherein the period P of the output power is the flickering interval of the bright spot of light. The output power of the laser generator 20 further defines the highest output level (peak output power) and the lowest output level, wherein the highest output level and the lowest output level are alternating with each other. In particular, the period P of the output is defined as a duty cycle of the highest output level and the lowest output level while the pulse duration T is defined as the duration of the highest output level. Therefore, the output power (rated power) of the laser generator 20 will be the average of the highest output level and the lowest output level within the period P. It is worth mentioning that the pulse width modulation (PWM) 13 preferably incorporates with the blue laser generator that the output power thereof is controlled to not exceed 5 mW continuous wave.

As shown in FIGS. 4 and 5, the threshold current is about 20-23 mA. Accordingly, at this current level, the laser generator 20 will still generate the laser beam. However, the laser beam is not stable. The operation current of the laser generator 20 is about 100 mA which can make the laser generator 20 to generate a stable laser beam. At this current level, the continue output power of the laser generator 20 is about 40-50 mW. Accordingly, the pulse width modulation (PWM) 13 modulates the input current as the operation current in a rectangular pulse wave form, such that the output power will be configured in a rectangular pulse wave form correspondingly. It is worth mentioning that the input peak current is about 60 mA, the output peak power is about 40 mW, and the output power (rated power) is about 4 mW. Therefore, the output power (rated power) of the laser generator 20 will not exceed 5 mW continuous wave.

According to the preferred embodiment, the laser aiming device further comprises an output power controller 30 operatively linked to the microcontroller unit 12 of the control module 10 for selectively adjust the output power of the laser generator 20. In particular, the output power controller 30 selectively adjusts the pulse duration T of the rectangular pulse wave in each period P thereof. When the pulse duration T is prolonged via the output power controller 30, the output power of the laser generator 20 will be increased.

In addition, the laser aiming device further comprises a temperature sensor 40 operatively linked to the microcontroller unit 12 of the control module 10 for detect an operation temperature of the laser generator 20. Accordingly, the output power controller 30 also selectively adjusts the pulse duration T of the rectangular pulse wave in each period P thereof in response to the operation temperature of the laser generator 20.

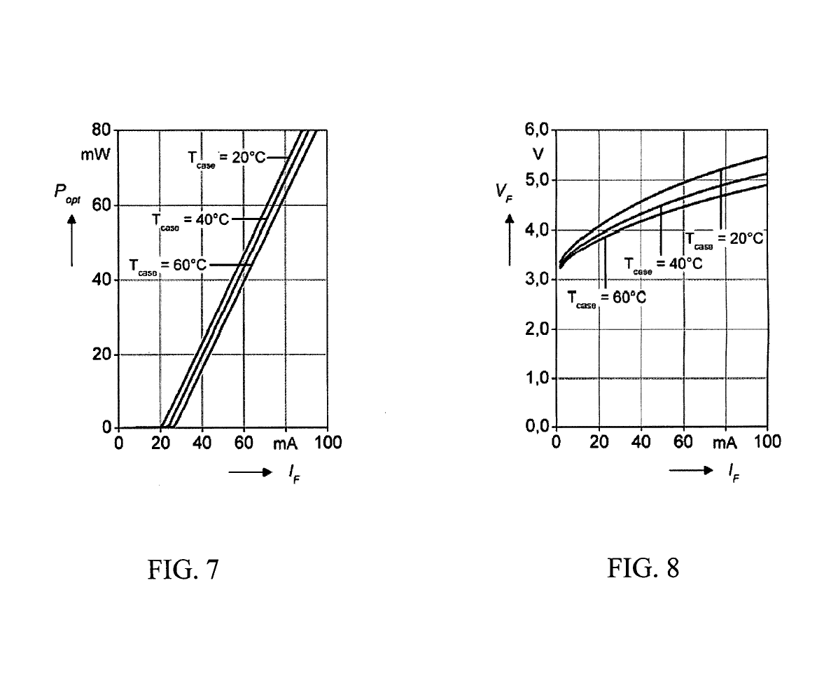

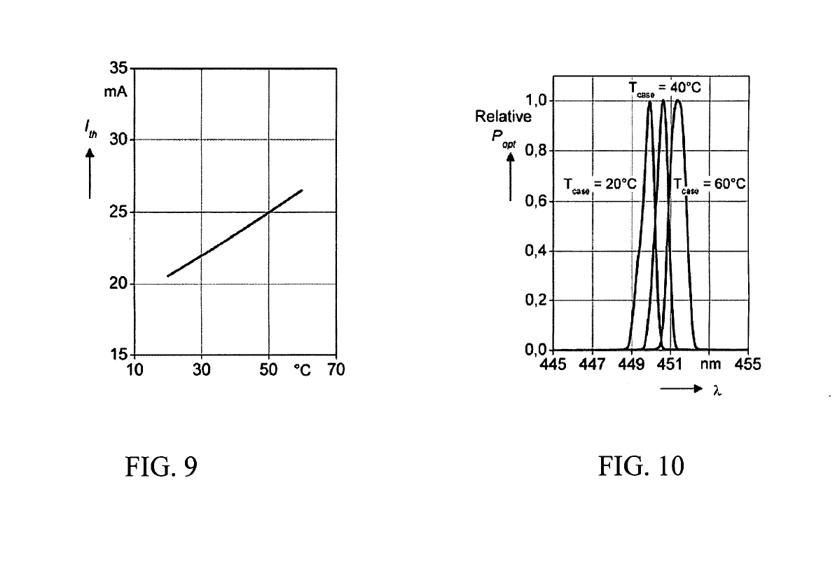

Accordingly, the laser generator 20 can be normally operated within an operative temperature range. Under the cold condition, i.e. the operation temperature of the laser generator 20 below the operative temperature range, the output power of the laser generator 20 will be decreased comparing with the normal operation temperature. Likewise, under the hot condition, i.e. the operation temperature of the laser generator 20 above the operative temperature range, the output power of the laser generator 20 will be increased. In order to control the output power of the laser generator 20, the output power controller 30 will selectively adjust the pulse duration T in response to the operation temperature of the laser generator 20. Under the cold condition, the output power controller 30 will prolong the pulse duration T in each period P, so as to increase the time of the output power of the laser generator 20 at the highest output level (peak output power). Under the hot condition, the output power controller 30 will reduce the pulse duration T in each period P, so as to reduce the time of the output power of the laser generator 20 at the highest output level. FIGS. 7-10 illustrate different parameters, such as output power, operating voltage, threshold current, and emission wavelength, in response to operation temperature.

It is worth mentioning that the output power controller 30 and the temperature sensor 40 are adapted to incorporate with red laser generator, green laser generator, or blue laser generator, in order to stabilize the output power thereof.

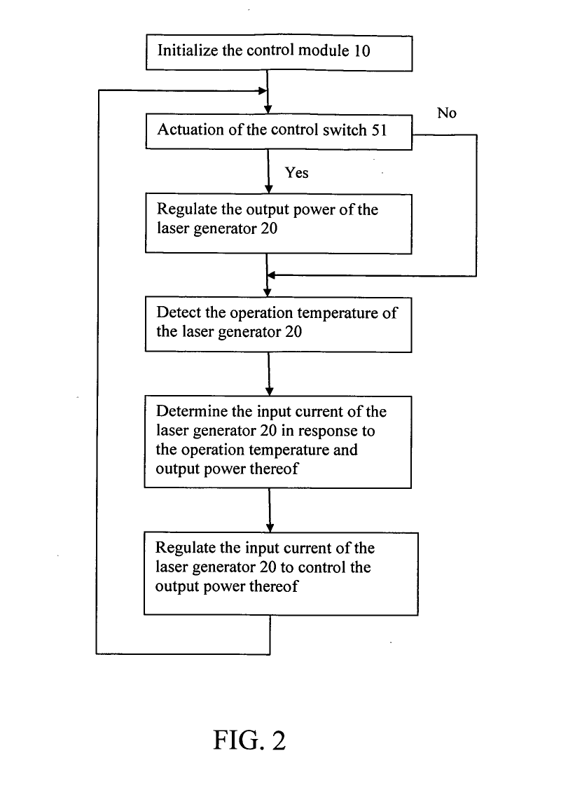

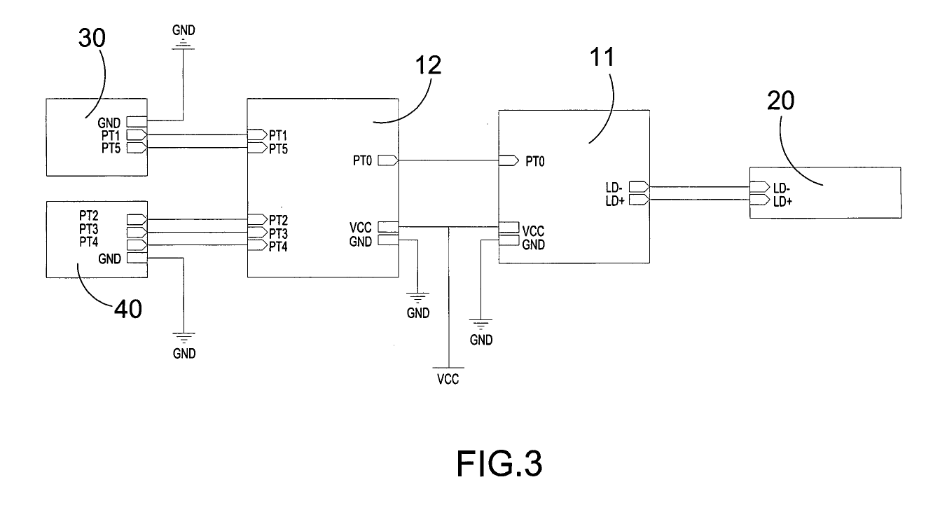

FIG. 2 illustrates the operation of the laser aiming device of the present invention. Accordingly, the control module 10 will be initialized at the time when the control switch 51 is actuated. Under the preset parameters, the control module 10 will regulate output power of the laser generator 20, such the laser generator 20 will be activated to generate the laser beam with a preset output power. The temperature sensor 40 will detect the operation temperature of the laser generator 20 under the preset parameters. In response to the operation temperature and the output power of the laser generator 20 as shown in FIGS. 7-10, the control module 10 will determine the input current of the laser generator 20 in order to modulate the operation current in a rectangular pulse wave form. As a result, by modulating the rectangular pulse wave form of the input current, the rectangular pulse wave form of output power of the laser generator 20 will be controlled being not exceed 5 mW continuous wave.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A laser aiming device, comprising:
a laser generator, and
a control module activating said laser generator to generate a non-continuous laser beam in order to form a bright spot of light in a flickering manner that a flickering interval of said bright spot of light is short enough not to be noticed by a human eye.

2. The laser aiming device, as recited in claim 1, wherein said laser generator is a blue laser generator to generate said non-continuous laser beam in blue color with an output power thereof being not exceed 5 mW continuous wave.

3. The laser aiming device, as recited in claim 1, wherein said control module comprises a pulse width modulation (PWM) to activate said laser generator in an on-and-off manner so as to enable said laser generator to generate said non-continuous laser beam.

4. The laser aiming device, as recited in claim 2, wherein said control module comprises a pulse width modulation (PWM) activating said laser generator in an on-and-off manner so as to enable said laser generator to generate said non-continuous laser beam.

5. The laser aiming device, as recited in claim 3, further comprising an output power controller operatively linked to said control module, wherein said pulse width modulation modulates said laser beam in form of rectangular pulse wave that said output power controller selectively adjusts a pulse duration of said rectangular pulse wave in each period thereof.

6. The laser aiming device, as recited in claim 4, further comprising an output power controller operatively linked to said control module, wherein said pulse width modulation modulates said laser beam in form of rectangular pulse wave that said output power controller selectively adjusts a pulse duration of said rectangular pulse wave in each period thereof.

7. The laser aiming device, as recited in claim 5, further comprising a temperature sensor operatively linked to said control module for detect an operation temperature of said laser generator, wherein said output power controller selectively adjusts said pulse duration of said rectangular pulse wave in each said period thereof in response to said operation temperature of said laser generator.

8. The laser aiming device, as recited in claim 6, further comprising a temperature sensor operatively linked to said control module for detect an operation temperature of said laser generator, wherein said output power controller selectively adjusts said pulse duration of said rectangular pulse wave in each said period thereof in response to said operation temperature of said laser generator.

9. A method of generating a low powered laser beam with an output power thereof being not exceed 5 mW continuous wave, comprising the steps of:
(a) operatively linking a laser generator to a control module; and
(b) activating said laser generator by said control module to generate a non-continuous laser beam in order to form a bright spot of light in a flickering manner that a flickering interval of said bright spot of light is short enough not to be noticed by a human eye, so as to control said output power of said non-continuous laser beam being not exceed 5 mW continuous wave.

10. The method as recited in claim 9 wherein, in the step (a), said laser generator is a blue laser generator to generate said non-continuous laser beam in blue color with said output power thereof being not exceed 5 mW continuous wave.

11. The method, as recited in claim 9, wherein the step (b) further comprises a step of (b.1) activating said laser generator in an on-and-off manner by a pulse width modulation (PWM) of said control module to enable said laser generator to generate said non-continuous laser beam.

12. The method, as recited in claim 10, wherein the step (b) further comprises a step of (b.1) activating said laser generator in an on-and-off manner by a pulse width modulation (PWM) of said control module to enable said laser generator to generate said non-continuous laser beam.

13. The method as recited in claim 11 wherein, in the step (b.1), said pulse width modulation modulates said laser beam in form of rectangular pulse wave.

14. The method as recited in claim 12 wherein, in the step (b.1), said pulse width modulation modulates said laser beam in form of rectangular pulse wave.

15. The method, as recited in claim 13 wherein the step (b.1) further comprises a step of selectively adjusting a pulse duration of said rectangular pulse wave in each period thereof by an output power controller which is operatively linked to said control module.

16. The method, as recited in claim 14 wherein the step (b.1) further comprises a step of selectively adjusting a pulse duration of said rectangular pulse wave in each period thereof by an output power controller which is operatively linked to said control module.

17. The method, as recited in claim 15, further comprising the steps of:
(c) detecting an operation temperature of said laser generator by a temperature sensor, and
(d) selectively adjusting said pulse duration of said rectangular pulse wave in each period thereof by said output power controller in response to said operation temperature of said laser generator.

18. The method, as recited in claim 15, further comprising the steps of:
(c) detecting an operation temperature of said laser generator by a temperature sensor, and
(d) selectively adjusting said pulse duration of said rectangular pulse wave in each period thereof by said output power controller in response to said operation temperature of said laser generator.

19. A blue laser aiming device, comprising:
a laser generator, and
a control module which comprises a driver circuit operatively linked to said laser generator and a microcontroller unit operatively controlling said driver circuit, wherein said laser generator is activated by said driver circuit to generate a non-continuous blue laser beam in order to form a bright spot of light in a flickering manner that a flickering interval of said bright spot of light is short enough not to be noticed by a human eye, wherein an output power of said non-continuous blue laser beam does not exceed 5 mW continuous wave.

20. The blue laser aiming device, as recited in claim 19, wherein said control unit comprises a pulse width modulation (PWM) activating said laser generator in an on-and-off manner and modulating said laser beam in form of rectangular pulse wave, so as to enable said laser generator to generate said non-continuous laser beam.

21. The blue laser aiming device, as recited in claim 20, further comprising an output power controller operatively linked to said microcontroller unit to selectively adjust a pulse duration of said rectangular pulse wave in each period thereof.

22. The blue laser aiming device, as recited in claim 21, further comprising a temperature sensor operatively linked to said microcontroller unit for detect an operation temperature of said laser generator, wherein said output power controller selectively adjusts said pulse duration of said rectangular pulse wave in each said period thereof in response to said operation temperature of said laser generator.

23. The laser aiming device, as recited in claim 1, wherein said driver circuit increases an input voltage from a power source to said laser generator in order to enable said laser generator to generate said laser beam in a stable manner.
